(19) United States
(12) Patent Application Publication
(10) Pub. No.: US 2004/0188773 A1
(43) Pub. Date: Sep. 30, 2004

(54) Semiconductor device having bit-line contacts, and method of manufacturing the same

(76) Inventors: Masaru Kidoh, Kawasaki-shi (JP); Ryota Katsumata, Yokohama-shi (JP); Hideaki Aochi, Kawasaki-shi (JP); Mutsuo Morikado, Yokohama-shi (JP); Masaru Kito, Yokohama-shi (JP)

Correspondence Address: FROMMER LAWRENCE & HAUG, 745 FIFTH AVENUE- 10TH FL., NEW YORK, NY, 10151, US

(21) Appl. No.: 10/786,442

(22) Filed: Feb. 25, 2004

(30) Foreign Application Priority Data
Mar. 31, 2003 (JP) 2003-095398

(51) Int. Cl. H01L 29/76

(52) U.S. Cl. 257/390

(57) ABSTRACT

In a cell-array region, bit-line contacts are self-aligned between the gate electrodes of adjacent gate transistors, with a first side insulating film interposed between each bit-line contact and the gate electrode of one transfer transistor. One end of each bit-line contact directly contacts the drain region of the transfer electrode.

### CROSS-REFERENCE TO RELATED APPLICATIONS

This application is based upon and claims the benefit of priority from prior Japanese Patent Application No. 2003-095398, filed Mar. 31, 2003, the entire contents of which are incorporated herein by reference.

### BACKGROUND OF THE INVENTION

1. Field of the Invention

The present invention relates to a semiconductor device and a method of manufacturing the same. More particularly, the invention relates to bit-line contacts for use in memory cell arrays that are designed for use in, for example, dynamic random-access memories (DRAMs) or embedded DRAM devices, and also relates to a method of manufacturing the bit-line contacts.

2. Description of the Related Art

The cell-array region of a DRAM or embedded DRAM device has insulated-gate transistors (MOSFETs) and capacitors. Each MOSFET functions as transfer gate in a memory cell. To provide the cell-array region, a silicide layer is formed by means of salicide process, on the polysilicon gate electrode and source-drain region of each MOSFET that functions as transfer gate. Then, a bit-line contact is formed the drain region shared by any two adjacent MOSFETs. In this case, it is difficult to form a cap insulating film (e.g., SiN film) on the polysilicon gate electrode after the salicide process has been carried out. In consequence, a bit-line contact self-aligned with two adjacent polysilicon gate electrodes, i.e., self-align contact, cannot be formed.

In view of this, polysilicon gate electrodes that lie adjacent to the region where a bit-line contact is to be formed are spaced apart by a long distance and a bit-line contact that is not self-aligned is formed. This method inevitably increases the area of the cell array. Hitherto, the drain-source region included in the cell-array region is subjected to silicidation, thus forming a silicide layer directly on the drain-source region. Consequently, junction leakage will probably increase.

Jpn. Pat. Appln. KOKAI Publication No. 2001-85643 discloses a DRAM in which only the peripheral circuits have been salicide-processed. Jpn. Pat. Appln. KOKAI Publication No. 2001-91535 discloses a DRAM in which all regions but the gate contact region have been salicide-processed.

As described above, it is impossible to form self-align contacts in the step of forming bit-line contacts in the memory cell array of the conventional DRAM or the conventional embedded DRAM device.

### BRIEF SUMMARY OF THE INVENTION

According to a first aspect of the invention, there is provided a semiconductor device comprising: a substrate; a cell-array region formed in the substrate and having a plurality of dynamic memory cells each of which includes a capacitor and a transfer transistor having a gate electrode, a drain region and a source region; first side insulating films formed on sides of the gate electrode of each transfer transistor; a peripheral region formed in the substrate, located adjacent to the cell-array region and including a transistor which has a gate electrode, a drain region and a source region; and a first contact which is self-aligned in the cell-array region, which is provided between the gate electrodes of any two adjacent transfer transistors, with two first side insulating films interposed between the first contact and the adjacent transfer transistors, and which has first and second ends, the first end directly contacting the drain regions of the adjacent transfer transistors.

According to a second aspect of the invention, there is provided a method of manufacturing a semi-conductor device, comprising: forming in a substrate a plurality of gate structures in surfaces of a cell-array region and a peripheral region of the substrate, each gate structure having a gate electrode and a cap insulating film formed on the gate electrode; forming first side insulating films on the sides of each gate structure; forming drain regions and source regions in the substrate, in self-alignment with the gate structures, respectively; burying gaps between the gate structures with first insulating film; planarizing a surface of the first insulating film; removing one first insulating film between two adjacent gate structures provided in the cell-array region, for making a first hole and exposing one drain region provided in the cell-array region; and forming a conductive film in the first hole, the conductive film being used as a first contact which contacts the drain region and which has a top lying at almost the same level as the surface of the first side insulating films.

### BRIEF DESCRIPTION OF THE SEVERAL VIEWS OF THE DRAWING

FIG. 1 is a sectional view schematically showing a part of a DRAM according to a first embodiment of the invention, which has an array of buried-strap (BS) type trench cells;

FIG. 2 is a sectional view for explaining some of the steps of manufacturing the DRAM shown in FIG. 1;

FIG. 3 is a sectional view explaining the step that follows the last of the steps shown in FIG. 2;

FIG. 4 is a sectional view explaining the step that follows the step shown in FIG. 3;

FIG. 5 is a sectional view explaining the step that follows the step shown in FIG. 4;

FIG. 6 is a sectional view explaining the step that follows the step shown in FIG. 5;

FIG. 7 is a sectional view explaining the step that follows the step shown in FIG. 7;

FIG. 8 is a sectional view explaining the step that follows the step shown in explained by FIG. 7;

FIG. 9 is a sectional view explaining the step that follows the step shown in FIG. 8;

FIG. 10 is a sectional view explaining the step that follows the step shown in FIG. 9;

FIG. 11 is a sectional view explaining the step that follows the step shown in FIG. 10;

FIG. 12 is a sectional view explaining the step that follows the step shown in FIG. 11;

FIG. 13 is a sectional view explaining the step that follows the step shown in FIG. 12;

FIG. 14 is a sectional view explaining the step that follows the step shown in FIG. 13;

FIG. 15 is a sectional view schematically depicting a surface-strap (SS) type trench cell according to a second embodiment of this invention;

FIG. 16 is a sectional view schematically showing an array of stack cells of capacitor-under bit line (CUB) type, according to a third embodiment of the invention;

FIG. 17 is a sectional view schematically showing a stack cell of capacitor-over bit line (COB) type, according to a fourth embodiment of the invention; and

FIG. 18 is a sectional view schematically depicting a SS-type trench having a FIN type transistor, according to a fifth embodiment of the present invention.

### DETAILED DESCRIPTION OF THE INVENTION

Embodiments of the present invention will be described in detail, with reference to the accompanying drawings.

(First Embodiment: SB-Type Trench DRAM)

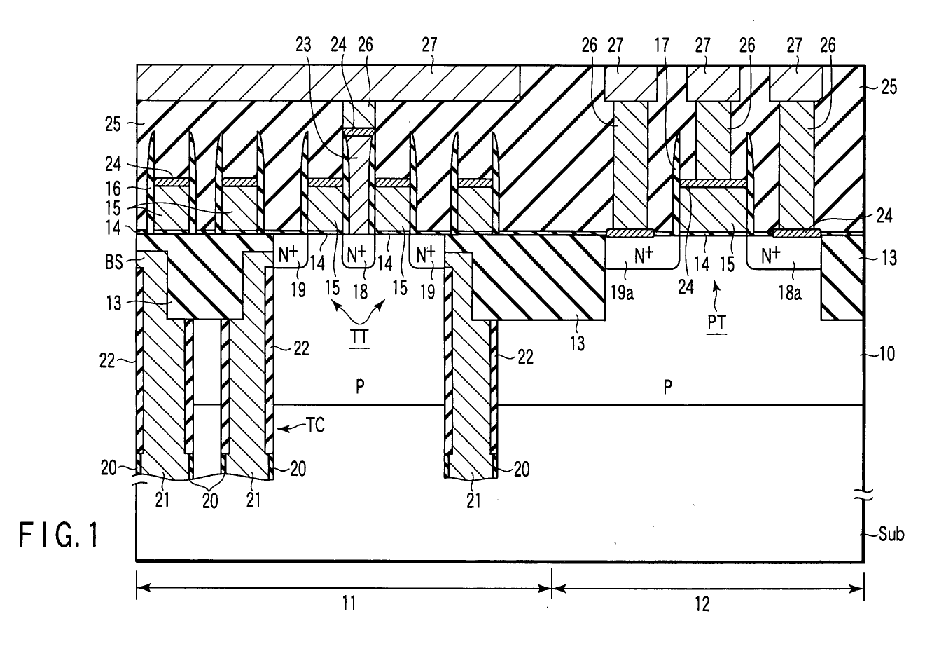

FIG. 1 is a sectional view schematically showing a part of a DRAM according to a first embodiment of the invention, which has an array of buried-strap (BS) type trench cells (DRAM cells).

As FIG. 1 shows, the DRAM has a substrate sub. It also has a P-type well region 10, a cell-array region 11 and a peripheral region 12, all provided in the upper surface of the substrate. Shallow-trench isolation (STI) regions 13 are formed in the upper surface of the substrate. An array of BS-type trench cells is formed in the cell-array region 11. A peripheral circuit that includes peripheral transistors is provided in the peripheral region 12. Each of the BS-type trench cells includes a BS-type trench capacitor and a transistor (NMOSFET) used as a transfer gate.

A thin gate insulating film 14 is formed on the substrate. Polysilicon gate electrodes 15 of the NMOSFETs are formed on the gate insulating film 14. (The polysilicon gate electrodes 15 constitute parts of word lines in the cell-array region 11.) Transistors TT are provided in the cell-array region 11 and used as transfer gates. Insulating films 16 are formed on both sides of the gate electrode 15 of each transistor TT. Impurity-diffused layers (N+) 18 and 19 are formed in the surface of the substrate; they are the source and drain regions of the transistors TT, respectively. A peripheral transistor PT is provided in the peripheral region 12. Insulating films 17 are formed on the sides of the gate electrode 15 of the peripheral transistor PT. Impurity-diffused layers (N+) 18a and 19a are formed in the surface of the substrate and used as the source and drain regions of the peripheral transistor PT.

The DRAM has BS-type trench capacitors TC, each comprising a capacitor insulating film 20 and a storage node 21. The capacitor insulating film 20 is formed in the inner surface of a trench and lies below the well region 10. The storage node 21 is buried in the trench. The storage node 21 is made of polysilicon, i.e., conductive silicon. A collar insulating film 22 is formed on the inner wall of the trench and lies above the capacitor insulating film 20. One of the shallow-trench isolation (STI) regions 13 lies between two adjacent trench capacitors TC. The isolation region 13 covers the top of the storage nodes 21 of either trench capacitor TC. In each of the storage nodes 21, a part of the storage node 21 between the collar insulating film 22 and STI 13 contacts the source region 19 of the NMOSFET TT used as a transfer gate.

The DRAM has bit-line contacts 23, only one of which is shown in FIG. 1. The bit-line contacts 23 are made of conductive silicon. (They are, for example, polysilicon plugs.) One of the contacts 23 is formed in self-alignment, between two insulating films 16 that are provided on the opposing sides of the gate electrodes 15 of two adjacent transistors TT used as transfer gates. This bit-line contact 23 contacts the drain region 18 that is shared by the two adjacent transistors TT.

The insulating films 16 formed on the sides of each gate provided in the cell-array region 11 and the insulating films 17 formed on the sides of the gate provided in the peripheral region 12 have almost the same height as the bit-line contact 23. Silicide layers 24 are formed on the upper surfaces of the gate electrodes 15, the upper surface of the bit-line contact (polysilicon plug) 23, the upper surface of the drain region 18a, and the upper surface of the source region 19a.

An inter-layer insulating film 25 covers the transistors TT used as transfer gates, peripheral transistor PT and bit-line contact 23. Metal-wire contacts 26 are formed in the inter-layer insulating film 25 and connected to the silicide layers 24 formed on bit-line contact 23, the gate electrode 15 of the peripheral transistor Pt, the drain region 18a and the source region 19a. Metal wires 27 are connected to the metal-wire contacts 26. The metal wires 27 include the bit lines provided in the cell-array region 11 and the gate lines, drain lines and source lines provided in the peripheral region 12.

In the process of manufacturing the cell-array region, a cap insulating film (e.g., SiN film, not shown) is formed on the polysilicon gate electrodes 15 and insulating films 16 are formed on the sides of each polysilicon gate electrode 15 and also on the sides of the cap insulting film. Then, a polysilicon plug is formed in the gap between selected two of the polysilicon gate electrodes 15. Thus, the bit-line contact 23 is provided in self-alignment. Thereafter, the silicide layers 24 are formed on the upper surfaces of word lines including the polysilicon gate electrodes 15 and on the upper surface of the bit-line contact 23 (i.e., polysilicon plug).

Hence, the silicide layer 24 provided on the upper surface of the polysilicon plug lies at a higher level than the silicide layer 24 provided on the surface of each word line. Note that the silicide layers 24 provided on the upper surfaces of the word lines and polysilicon plug are made of the same material. The silicide layers 24 is composed of, for example, a Co layer, a Ti layer and a TiN layer that are laid one on another in the order mentioned.

The peripheral transistor provided in the peripheral region 12 is made in the same way as the transistors provided in the cell-array region 11. Precisely, a cap insulating film (e.g., SiN film, not sown) is formed on the polysilicon gate electrode 15, and insulating films 17 are formed on the sides of the polysilicon gate electrode 15 and also on the sides of the cap insulting film. Hence, the insulating films 17 have a greater height than the gate electrode 15 and their tops are almost at the same level as the top of the bit-line contact 23 (i.e., polysilicon plug) provided in the cell-array region 11. Thereafter, the cap insulating film is removed. Next, a salicide process is carried out, forming three silicide layers 24 on the upper surfaces of the gate electrode 15, the upper surface of the drain region 18a and the upper surface of the source region 19a, respectively. The silicide layers thus formed reduce the resistances of the gate electrode 15, drain region 18a and source region 19a.

In the manufacture of the DRAM having the structure described above, a SAC process is performed, providing the bit-line contact 23 made of polysilicon, without performing silicidation on the surface of the cell-array region 11. Then, a salicide process is carried out, forming silicide layers 24 on the upper surface of the polysilicon gate electrodes 15 (each being a part of a word line) provided in the cell-array region 11, the upper surface of the bit-line contact 23, the upper surface of the polysilicon gate electrode 15 provided in the peripheral region 12, and the upper surface of the drain region 18a, and the upper surface of the source region 19a. The silicide layers 24 reduce the resistances of the polysilicon gate electrodes 15, bit-line contact 23, drain region 18a and source region 19b. Since no silicidation is performed on the surface of the cell-array region 11, it is possible to decrease the junction leakage.

As indicated above, the SAC process is carried out, forming the bit-line contact 23 made of conductive silicon. Formed by the SAC process, the bit-line contact 23 can be made narrow. The space between the adjacent polysilicon gate electrodes 15, in which the bit-line contact 23 is formed, can therefore be smaller than in the conventional DRAM. This makes it possible to reduce the size of the cell array.

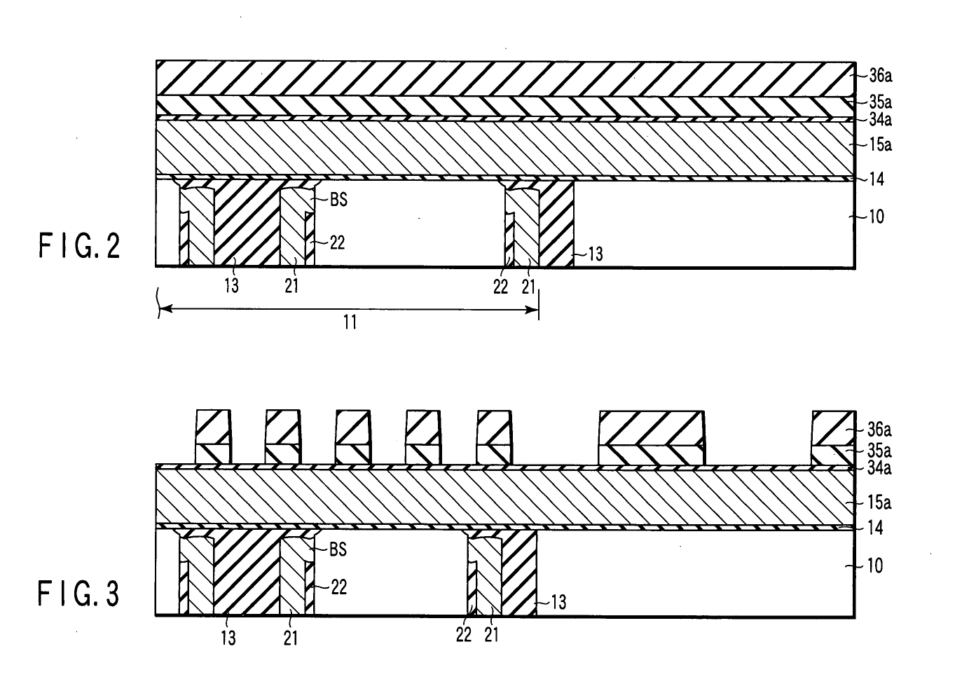

FIGS. 2 to 14 schematically illustrate a method of manufacturing the DRAM that has BS-type trench cells of the structure shown in FIG. 1. To be more specific, FIGS. 2 to 14 depict the upper part of the well region 10.

First, a plurality of trench capacitors TC are formed in the upper surface of the cell-array region 11 of the substrate sub, as is illustrated in FIG. 2. The process of forming the trench capacitors TC will not be described because it is not essential to the present embodiment of the invention. After the trench capacitors TC are. formed, shallow-trench isolation (STI) regions 13 are formed between the trench capacitors, and buried straps (BSs) are formed in the upper surface of the substrate. Next, a well region 10 is formed in the upper surface of the substrate.

Thereafter, a gate insulating film 14 is formed on the substrate. Polysilicon is deposited on the gate insulating film 14, forming a polysilicon layer 15a that will be processed into gate electrodes. An SiN film 34a is formed on the polysilicon layer 15a. The SiN film 34a is used as a stopper. A BSG film 35a, which is a mask, is formed on the SiN film 34a. Next, an SiN film 36a, which is a cap layer, is formed on the BSG film 35a.

Next, a PEP (Photo Engraving Process) is performed, forming a resist pattern (not shown) that will be used to form gate electrodes. Using the resist pattern as mask, RIE (Reactive Ion Etching) is carried out, thus patterning the cap SiN film 36a and mask BSG film 35a, as is illustrated in FIG. 3.

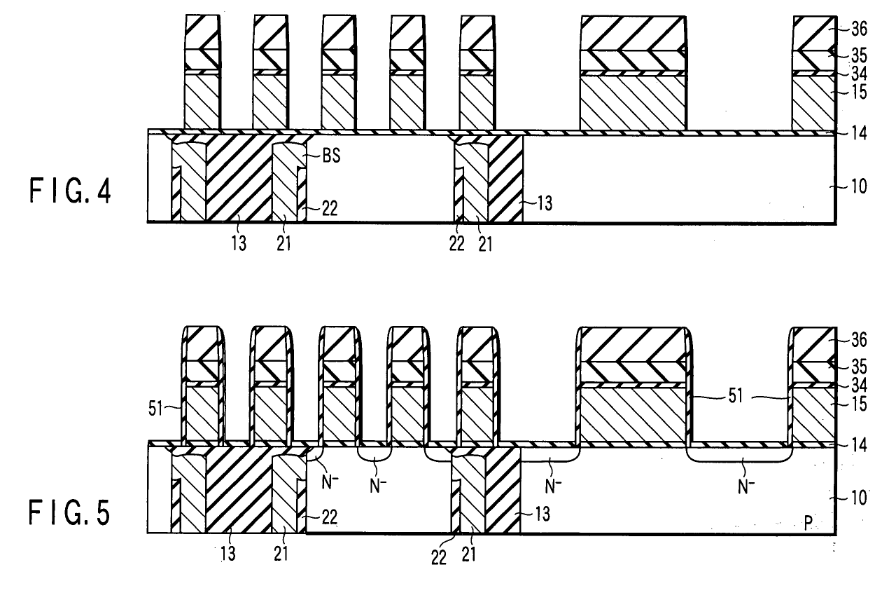

Using the mask SiN film 36a and the mask BSG film 35a, both patterned, as masks, RIE is performed, patterning the polysilicon layer 15a as shown in FIG. 4. As a result, polysilicon gate electrodes 15 are formed. Thus, the SiN film 34a, the BSG film 35a and the SiN film 36a, which are used as a cap insulating layer, are left on each gate electrode 15, one laid upon another in the order mentioned.

Thereafter, the upper surface of the substrate is oxidized, forming a protective film (Ox film) 51 on the gate insulating film (Ox film) 14, gate electrodes 15 and the cap insulating film, as is illustrated in FIG. 5. Using the resultant structure as mask, impurity ions are implanted at a low concentration into the substrate. As a result, a low-concentration region(N−) is formed in the drain and source regions of the substrate. The low-concentration region will be used to provide LDD-type transistors.

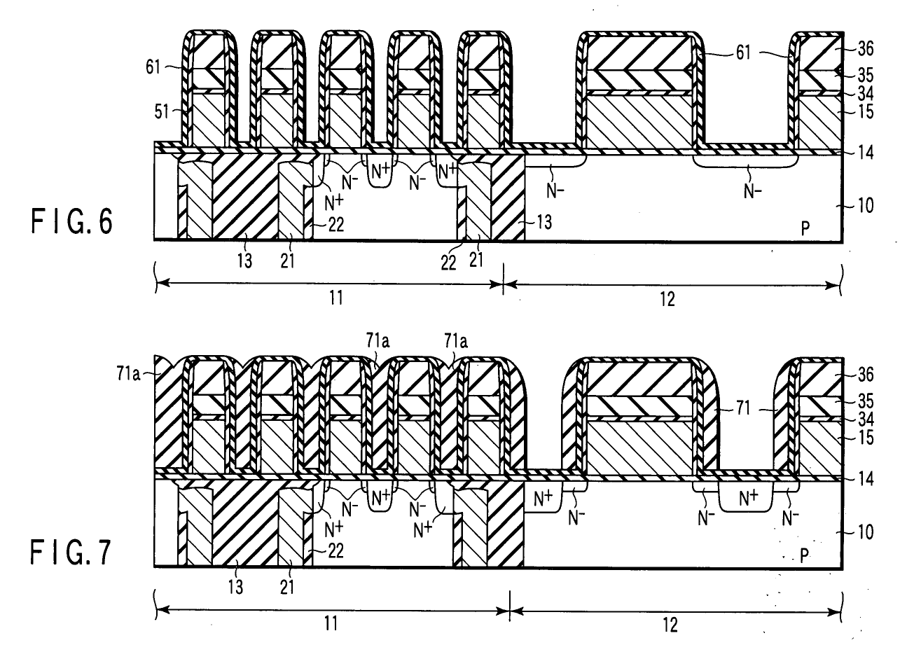

As FIG. 6 shows, SiN is deposited on the upper surface of the substrate by means of CVD, forming an SiN film. The SiN film is subjected to RIE. An SiN film 61, which will be used as sidewall spacer, is formed on the protective film (Ox) 51 that is formed on the gate electrodes provided in the cell-array region 11. At the same time, an SiN film 61 is formed, as a barrier, on the peripheral region 12. Thereafter, impurity ions are implanted at a high concentration into the cell-array region 11 of the substrate, forming high-concentration drain and source regions (N+) of transistors.

Further, TEOS is deposited by means of CVD, forming a TEOS film 71a on the upper surface of the substrate as is illustrated in FIG. 7. Note that the TEOS film 71a fills the gaps between the gate electrodes 15. Parts of the TEOS film 71a are removed, forming TEOS films 71 that are used as spacers at the sides of the gates. Next, using the resultant structure as mask, impurities are injected at a high concentration into the substrate, forming the drain and source regions of transistors in the peripheral region 12.

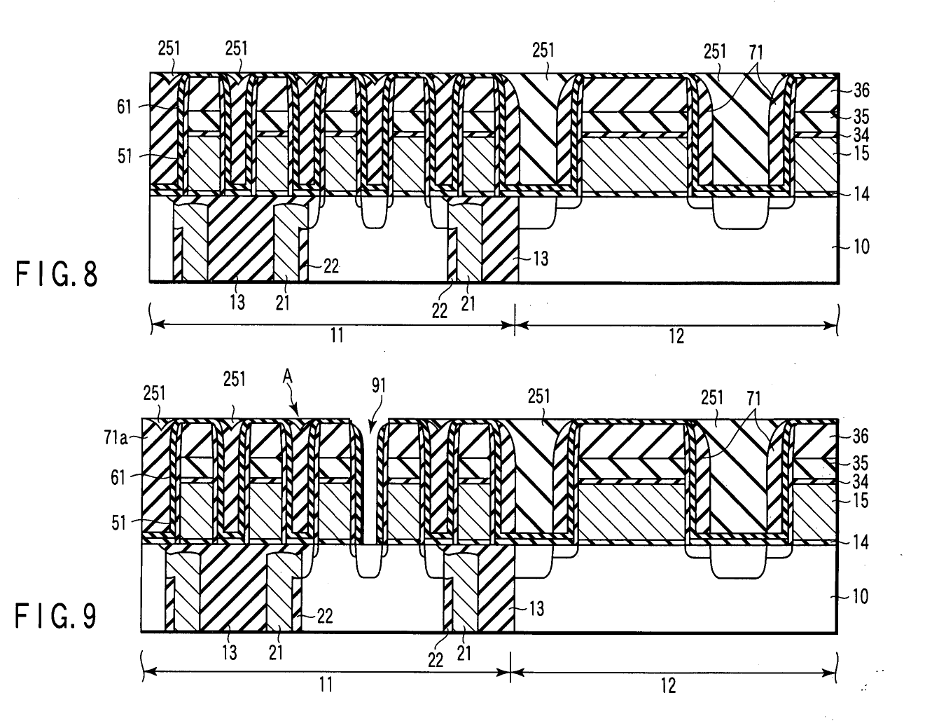

Next, a BSG film (or BPSG film) 251 is formed by CVD on the upper surface of the substrate. Then, CMP (Chemical Mechanical Polishing) is performed on the BSG film 251, and the BSG film (or BPSG film) 251 is planarized as shown in FIG. 8. As a result, the BSG film (or BPS film) 251 fills the gaps between the gate electrodes that are provided in the peripheral region 12.

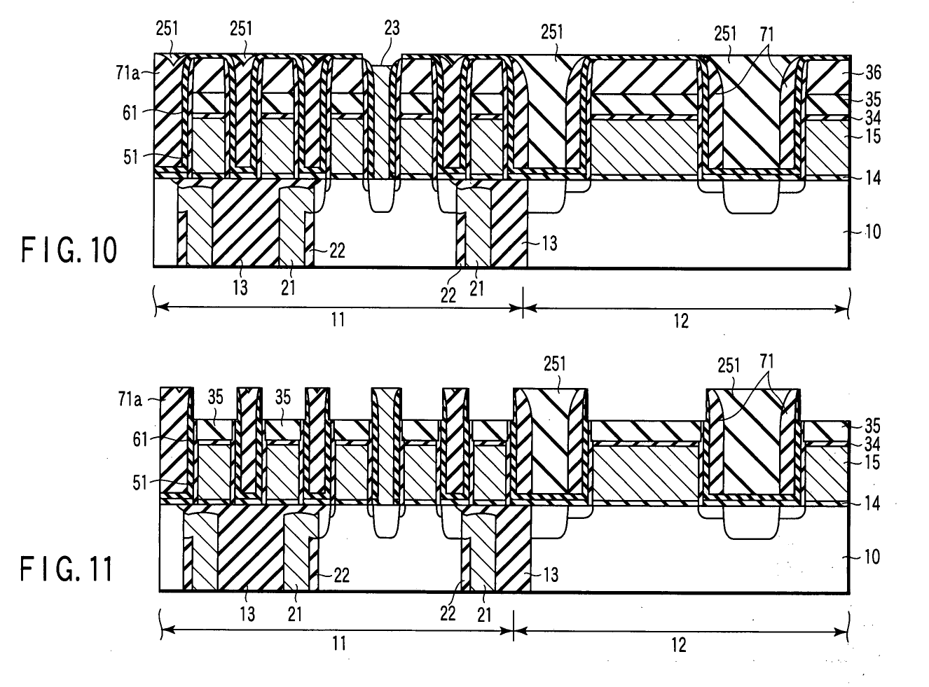

PEP and RIE are performed, removing that part of the TEOS film 71a which lies as barrier in the gaps between two gate electrodes 15 provided in the cell-array region 11 as illustrated in FIG. 9. This SAC process makes a hole 91, exposing the drain region (region 18 shown in FIG. 1) that is shared by two adjacent transistors.

P-type amorphous silicon (P-aSi) is then deposited by means of CVD, forming an amorphous silicon layer as shown in FIG. 10. Then, RIE, for example, is carried out, thereby imparting a flat surface to the amorphous silicon layer. As a result, a bit-line contact 23 is formed in the contact hole 91. The top of the bit-line contact 23 is etched, making a recess.

Thereafter, as shown in FIG. 11, the protective film 51 and cap SiN film 36, both provided on the polysilicon gate electrodes 15, are etched back.

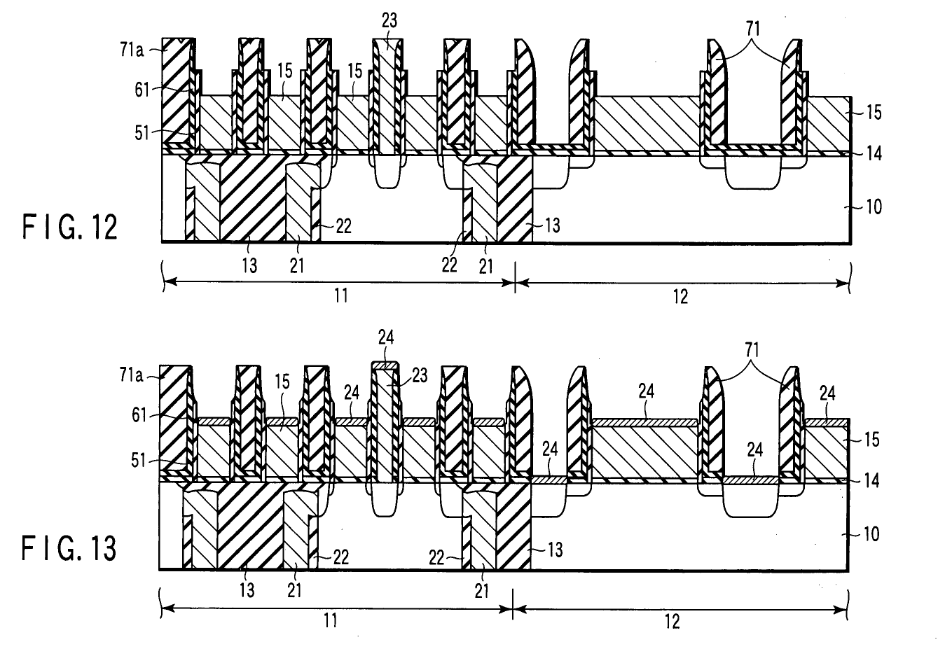

As FIG. 12 illustrates, the BSG films 35 and SiN films 34 are removed from the polysilicon gate electrodes 15. Further, the BSG films 251 are removed from the drain region 18a and source region 19a (see FIG. 1), both provided in the peripheral region 12.

As shown in FIG. 13, the gate insulating films 14 are removed from the drain and source regions provided in the peripheral region 12. Then, a salicide process is performed, forming silicide films 24 on the upper surface of each polysilicon gate electrode 15, the upper surface of the bit-line contact 23 and the upper surfaces of the drain and source regions provided in the peripheral region 12. In the salicide process, Co film, Ti film and TiN film are formed by sputtering, rapid thermal annealing (RTA) is carried out for the first time, non-reactive wet etching is effected, and RTA is performed for the second time.

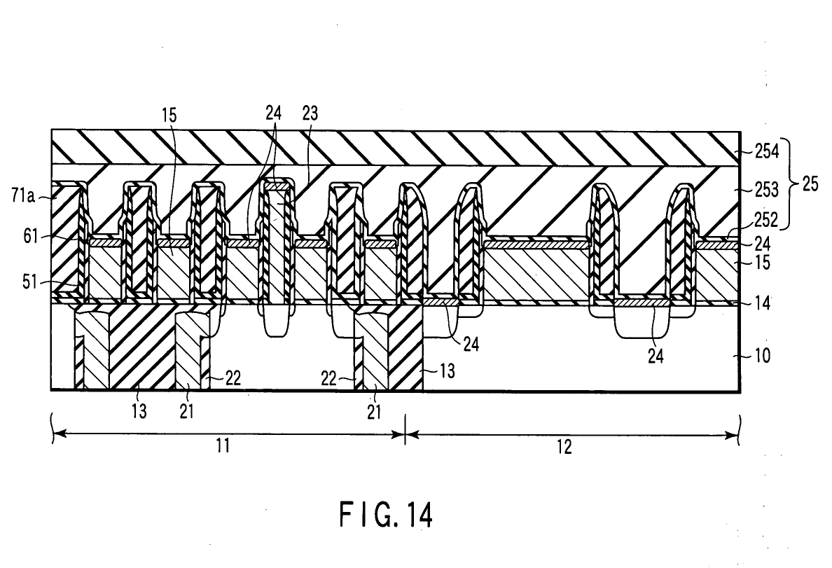

Next, an inter-layer insulating film 25 is formed on the upper surface of the substrate as is illustrated in FIG. 14. The inter-layer insulating film 25 is composed of three films 252, 253 and 254 laid one upon another. The lower film 252 is an SiN film. The intermediate film 253 is an NSG film (or O₃TEOS film). The upper film 254 is a plasma TEOS film. First, the SiN film 252 is formed on the upper surface of the substrate. Then, the NGS film 253 (or O₃TEOS film) is deposited on the SiN film 252. CMP is performed. Thereby, the NGS film (or O₃TEOS film) 253 is planarized. Further, the plasma TEOS film 254 is deposited on the NGS film (or O₃TEOS film) 253. Thereafter, as is illustrated in FIG. 1, metal-wire contacts 26 and metal wires 27 are formed in the inter-layer insulating film 25. The contacts 26 are connected to the bit-line contact 32 and the gate electrode and source and drain regions of the transistor provided in the peripheral region 12.

It should be noted that parts of the steps shown in FIGS. 6 and 7 may be a process performed on the cell-array region 11 and another process performed on the peripheral region 12.

(Second Embodiment: SS-Type Trench DRAM)

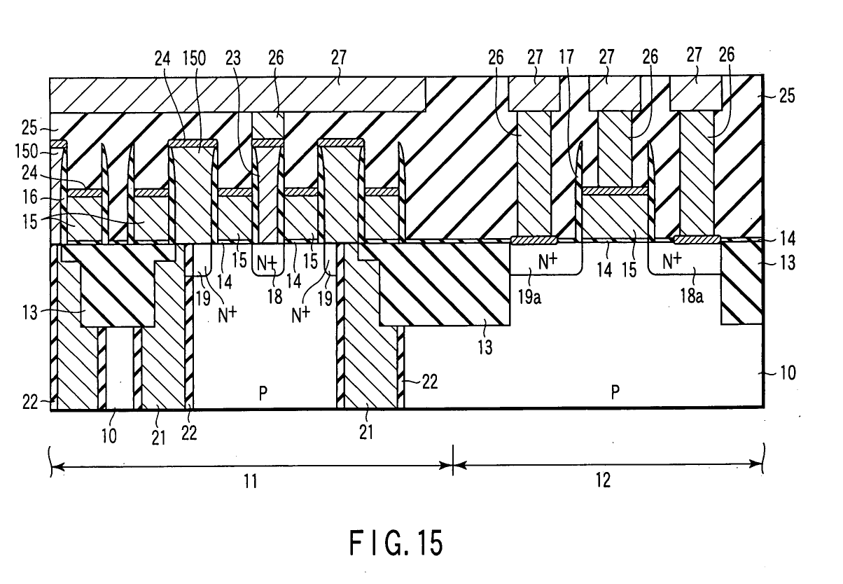

FIG. 15 is a sectional view schematically depicting a part of the second embodiment of this invention. The second embodiment is a DRAM that has an array of surface-strap (SS) type trench cells formed in the surface of a silicon substrate.

In the SS-type trench cell shown in FIG. 15, a storage-node contact 150 connects the storage node of the trench capacitor to the source region 19 of the transistor used as transfer gate. The storage-node contact 150 has been formed by a SAC process. The contact 150 is made of polysilicon having conductivity, like the gate electrode 15. A silicide layer 24 is provided on the upper surface of the storage-node contact 150. The DRAM is identical to the DRAM shown in FIG. 1, in any other structural respects. Hence, the components identical to those shown in FIG. 1 are designated at the same reference numerals.

The method of manufacturing the DRAM having SS-type trench cells comprises almost the same steps as explained with reference to FIGS. 2 to 14. How this DRAM is manufactured will be described. First, trench capacitors TC are formed. After the trench capacitors TC are formed, shallow-trench isolation (STI) regions 13 are formed between the trench capacitors. At this time, the upper surface of each collar insulating film 22 is in flush with the surface of the substrate, and each storage node 21 is exposed through the gap between one STI region 13 and one collar insulating film 22. Thus, the storage nodes 21 are exposed at the surface of the substrate. Next, a well region 10 is formed in the upper surface of the substrate.

Thereafter, a gate insulating film 14 is formed on the substrate. Polysilicon is deposited on the gate insulating film 14, forming gate electrodes 15. An insulating film 16 is formed on each gate electrode 15 and a cap insulating film (not shown). Thereafter, impurity ions are implanted into the substrate, forming drain and source regions of transistors. The gaps between the gate electrodes are filled with an insulating film, and the insulating film is planarized. Next, a SAC process is carried out, forming a storage-node contact 150 and a bit-line contact 23. The storage-node contact 150 is provided on the storage node 21 and the source region 19. The contact 150 therefore connects the storage node 21 and the source region 19 together. The bit-line contact 23 is provided on the drain region 18. Thereafter, the cap insulating film (not shown) is removed. A salicide process is carried out, forming silicide layers 24 on the gate electrodes 15, the drain region 18a and source region 19a provided in the peripheral region 12. Then, metal-wire contacts 26 and metal wires 27 are formed in the inter-layer insulating film 25.

Contact holes in which the storage nodes are provided are made at the same time as the contact hole in which the bit-line contact is provided. More precisely, the contact hole for the storage nodes are made in the region A shown in FIG. 9, at the same time the contact hole 91 for the bit-line contact is made.

In the DRAM having SS-type trench cells, which is the second embodiment of the invention, the storage-node contact 150 and the bit-line contact 23 are formed at the same time. This helps to decrease the number of manufacturing steps and to reduce the widths of the storage-node contact 150 and bit-line contact 23, both provided in the cell-array region 11. Hence, an increase in the area of the cell-array region 11 can be prevented.

(Third Embodiment: CUB-Type Stack DRAM)

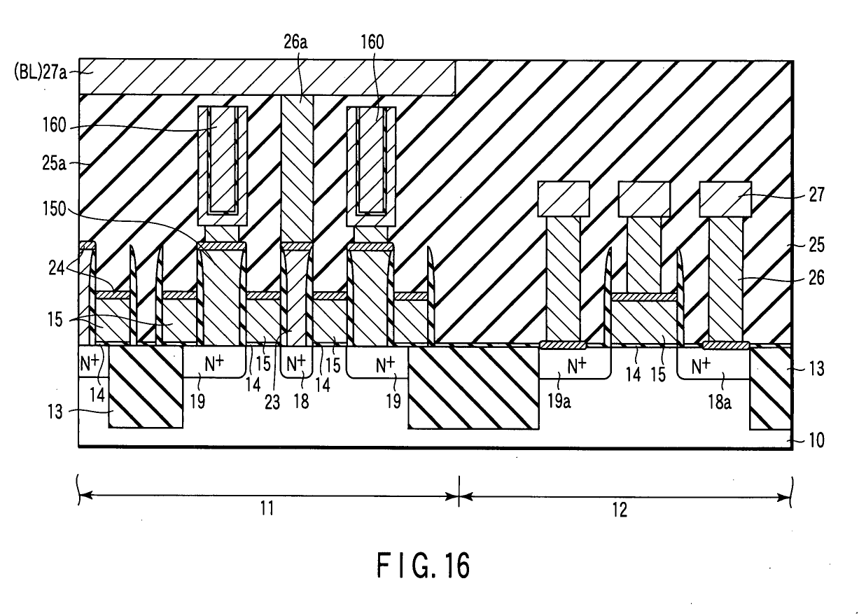

FIG. 16 is a sectional view schematically illustrating a part of the third embodiment of this invention. The third embodiment is a DRAM that has an array of capacitor-under bit line (CUB) type trench cells formed in the surface of a silicon substrate.

In the CUB-type stack cell shown in FIG. 16, a stack capacitor is provided, in place of a trench capacitor, between a bit line and the substrate. The CUB-type stack cell is identical to the BS-type trench cells shown in FIG. 1, in any other structural respects. Hence, the components identical to those shown in FIG. 1 are designated at the same reference numerals.

A method of manufacturing the DRAM having CUB-type stack cells, shown in FIG. 16, will be described. First, isolation regions 13, such as STI regions, are formed in the substrate. A well region 10 is formed in the upper surface of the substrate. A gate insulating film 14 is formed on the surface of the substrate. Gate electrodes 15 made of polysilicon are formed on the gate insulating film 14. Insulating films are formed on the sides of the polysilicon gate electrode 15 and also on the sides of the cap insulting film (not shown). Thereafter, impurity ions are implanted into the substrate, forming drain and source regions of transistors. The gaps between the gate electrodes are filled with an insulating film, and the insulating film is planarized. Next, a SAC process is carried out, forming storage-node contacts 150 and a bit-line contact 23. The storage-node contacts 150 are provided on the source regions 19. The bit-line contact 23 is provided on the drain region 18. The cap insulating film is removed. A salicide process is carried out, forming silicide layers 24 on the gate electrodes 15, the bit-line contact 23, the storage-node contacts 150, and the drain region 18a and source region 19a provided in the peripheral region 12. Then, an inter-layer insulating film 25 is formed on the peripheral region 12. In the inter-layer insulating film 25, metal-wire contacts 26 are formed. Also in the film 25, metal wires 27 are formed on the metal-wire contacts 26. Thereafter, an inter-layer insulating film 25a is formed on the cell-array region 11. In the inter-layer insulating film 25a, stack capacitors 160 are formed on the storage-node contacts 150. A metal-wire contact 26a is formed in the upper surface of the inter-layer insulating film 25a, in contact with the bit-line contact 23. The structure of the stack capacitors 160 is not limited to the one shown in FIG. 16.

In the third embodiment, i.e., a DRAM having CUB-type stack cells, the bit-line contact 23 and the storage-node contacts 150 are formed at the same time. This reduces the number of manufacturing steps. Further, the widths of the bit-line contact 23 and storage-node contacts 150 can be decreased. Hence, an increase in the area of the cell-array region 11 can be prevented, because the contacts 23 and 150 are provided in the cell-array region 11.

(Fourth Embodiment: COB-Type Stack DRAM)

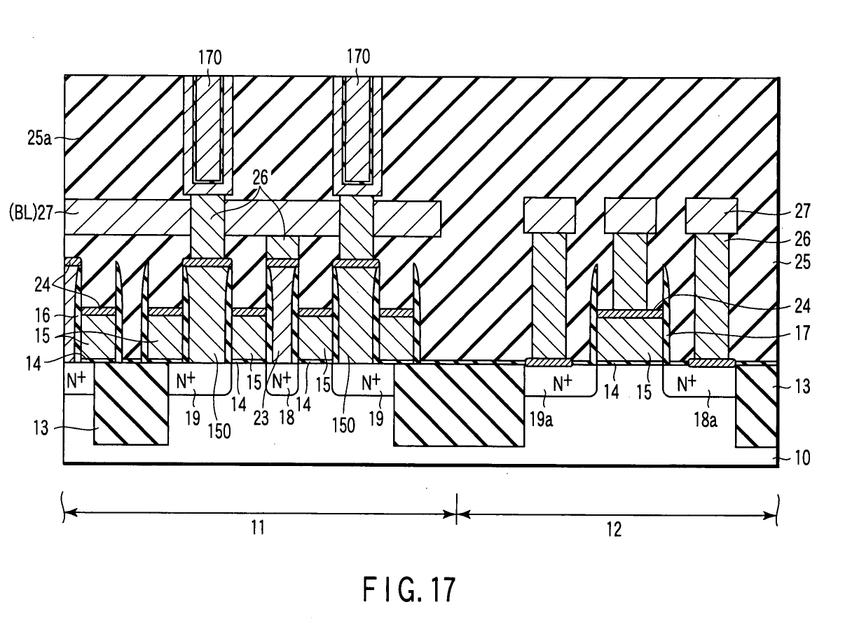

FIG. 17 is a sectional view schematically illustrating a part of the fourth embodiment of this invention. The fourth embodiment is a DRAM that has an array of capacitor-over bit line (COB) type trench cells formed in the surface of a silicon substrate.

In the COB-type stack cell shown in FIG. 17, a stack capacitor is provided, in place of a trench capacitor, above the bit line. The COB-type stack cell is identical to the BS-type trench cells shown in FIG. 1, in any other respects. Hence, the components identical to those shown in FIG. 1 are designated at the same reference numerals.

A method of manufacturing the DRAM having COB-type stack cells, shown in FIG. 17, will be described. First, isolation regions 13, such as STI regions, are formed in the substrate. A well region 10 is formed in the upper surface of the substrate. A gate insulating film 14 is formed on the surface of the substrate. Gate electrodes 15 made of polysilicon are formed on the gate insulating film 14. Insulating films are formed on the sides of the polysilicon gate electrode 15 and also on the sides of the cap insulting film (not shown). Thereafter, impurity ions are implanted into the substrate, forming drain regions 18 and source regions 19 of transistors. The gaps between the gate electrodes are filled with an insulating film, and the insulating film is planarized. Next, a SAC process is carried out, forming storage-node contacts 150 and a bit-line contact 23. The storage-node contacts 150 are provided on the source regions 19. The bit-line contact 23 is provided on the drain region 18. The cap insulating film is removed. A salicide process is carried out, forming silicide layers 24 on the gate electrodes 15, the bit-line contact 23, the storage-node contacts 150, and the drain region 18a and source region 19a provided in the peripheral region 12.

Then, an inter-layer insulating film 25 is formed on the upper surface of the entire structure. In the inter-layer insulating film 25, metal-wire contacts 26 and metal wires 27 are formed. The metal-wire contacts 26 formed in the cell-array region 11 are connected to the storage-node contacts 150 and bit-line contact 23, respectively. The metal-wire contacts 26 formed in the peripheral region 12 are connected to the gate electrode 15 and the drain region 18a and source region 19a that are provided in the peripheral region 12. In the cell-array region 11, the metal-wire contacts 26 and metal wire 27 are formed at the same time. In the cell array, metal wire 27 connected to the bit-line contact 26 is a bit line, for example.

Next, an inter-layer insulating film 25a is formed on the upper surface of the resultant structure. In the cell-array region 11, stack capacitors 170 are formed in the inter-layer insulating film 25a. The stack capacitors 170 are located above the metal wire 27 that serves as the bit line and in alignment with the storage-node contacts 150. The metal-wire contacts 26 connect the stack capacitors 170 to the storage-node contacts 150.

The fourth embodiment achieves the same advantages as the third embodiment. The structure of the stack capacitors 170 is not limited to the one shown in FIG. 17.

(Fifth Embodiment: SS-Type Trench DRAM with FIN-Type Transistors)

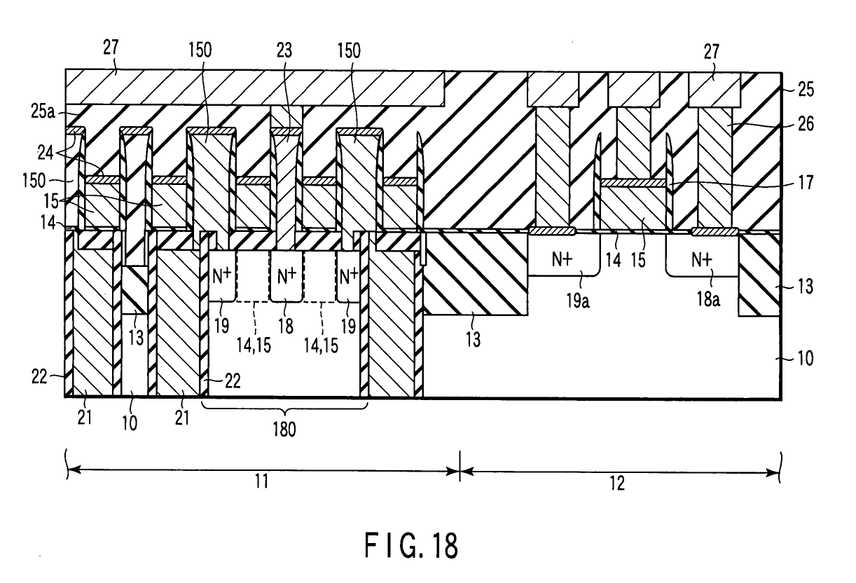

FIG. 18 is a sectional view schematically illustrating a part of the fifth embodiment of the invention. The fifth embodiment is a DRAM that has an array of SS-type trench cells formed in the surface of a silicon substrate and having a FIN-type transistor.

The SS-type trench cell having an FIN-type transistor, which is shown in FIG. 18, is different from the SS-type trench cell shown in FIG. 15 in one respect only. That is, it has a transistor region 180 in which a FIN-type transistor used as a transfer gate is formed. Hence, the components identical to those shown in FIG. 15 are designated at the same reference numerals.

The transistor region 180 has an active part, a cap insulating film, gate-insulating films 14, gate electrodes 15, a drain region 18, and source regions 19. The active part is provided in the substrate and has a projection. The cap insulating film (e.g., SiN film) is provided on the upper surface of the active part. The gate electrodes 15 are made of polysilicon and located on the sides of the projection, with gate insulating films 14 interposed between the projection and the electrodes 15. The drain region 18 and the source regions 19 are located beside the gate electrodes 15, respectively, and insulted thereform by the gate insulating films 14.

A of manufacturing the DRAM having FIN-type transistors and SS-type trench cells, shown in FIG. 18, will be described. At first, isolation regions are formed in the substrate. A well region 10 is formed in the upper surface of the substrate. Next, an active part having a projection is formed in the substrate. Gate insulating film is formed on the sides of the projection of the active part. Polysilicon is deposited on the gate insulating film, forming polysilicon layer. The polysilicon layer is planarized. Further, a cap insulating film (not shown) is formed on the polysilicon layer. SS-type trench capacitors are formed in the well region 10 and substrate, in the same way as in the first embodiment. The polysilicon layer and the gate insulating film are etched, thus forming gate electrodes 15 of FIN-type transistors, in the cell-array region 11. Thereafter, impurity ions are implanted into those portions of the active portion which lie beside the gate electrodes 15. As a result, the drain region 18 and source regions 19 of the FIN-type transistors are formed in the cell-array region 11. Next, in the peripheral region 12, gate electrodes 15 are formed on the gate insulating film 14. The gaps between the gate electrodes 15 are filled with insulating film, and the insulating film is planarized. Next, a SAC process is carried out, forming storage-node contacts 150 and a bit-line contact 23. The storage-node contacts 150 are provided on the storage-nodes 21 and the source regions 19. The bit-line contact 23 is provided on the drain region 18. The cap insulating film is removed. A salicide process is carried out. Further, an inter-layer insulating film 25 is formed on the upper surface of the entire structure. In the inter-layer insulating film 25, metal-wire contacts 26 are formed and metal wires 27 are then formed.

In the fifth embodiment, too, the bit-line contact 23 and the storage-node contacts 150 can be formed at the same time. This reduces the number of manufacturing steps.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate;
a cell-array region formed in the substrate and having a plurality of dynamic memory cells each of which includes a capacitor and a transfer transistor having a gate electrode, a drain region and a source region;
first side insulating films formed on sides of the gate electrode of each transfer transistor;
a peripheral region formed in the substrate, located adjacent to the cell-array region and including a transistor which has a gate electrode, a drain region and a source region; and
a first contact which is self-aligned in the cell-array region, which is provided between the gate electrodes of any two adjacent transfer transistors, with two first side insulating films interposed between the first contact and the adjacent transfer transistors, and which has first and second ends, the first end directly contacting the drain regions of the adjacent transfer transistors.

2. The device according to claim 1, wherein a silicide layer is formed by means of salicide process on a word line which includes the gate electrode and the second end of the first contact.

3. The device according to claim 2, wherein the first side insulating films have tops which lie at a level higher than the surface of the silicide layer provided on the gate electrode.

4. The device according to claim 2, wherein the surface of the silicide layer provided on the upper surface of the first contact lies at a level higher than the surface of the silicide layer provided on the word line.

5. The device according to claim 4, wherein the silicide layer on the upper surface of the word line and the silicide layer on the upper surface of the first contact are of the same material.

6. The device according to claim 4, wherein second side insulating films are formed on the sides of the gate electrode of the transistor provided in the peripheral region and have tops which lie at a level higher than the surface of the gate electrode of the transistor.

7. The device according to claim 1, wherein the capacitor is a buried-strap type trench capacitor.

8. The device according to claim 1, further comprising a second contact which is self-aligned in the cell-array region, which is provided between the gate electrodes of any two adjacent transfer transistors, with two first side insulating films interposed between the second contact and the adjacent transfer transistors, and which has first and second ends, the first end directly contacting the source regions of the adjacent transfer transistors.

9. The device according to claim 8, wherein the capacitor is a surface-strap type trench capacitor which has a storage node that is connected to the source region by the second contact.

10. The device according to claim 8, wherein the capacitor is a stack capacitor which is formed on the second contact, is located above the bit line and constituting a capacitor-over bit line type stack cell.

11. The device according to claim 8, wherein the capacitor is a stack capacitor which is formed on the second contact, is located below the bit line and constitutes a capacitor-under bit line type stack cell.

12. The device according to claim 8, wherein each of the dynamic memory cells is formed in the silicon substrate, comprises an FIN-type transistor and a trench capacitor and constitutes a surface-strap type trench cell which has a storage node connected to the source region by the second contact.

13. A method of manufacturing a semiconductor device, comprising:
forming in a substrate a plurality of gate structures in surfaces of a cell-array region and a peripheral region of the substrate, each gate structure having a gate electrode and a cap insulating film formed on the gate electrode;
forming first side insulating films on the sides of each gate structure;
forming drain regions and source regions in the substrate, in self-alignment with the gate structures, respectively;
burying gaps between the gate structures with first insulating film;
planarizing a surface of the first insulating film;
removing one first insulating film between two adjacent gate structures provided in the cell-array region, for making a first hole and exposing one drain region provided in the cell-array region; and
forming a conductive film in the first hole, the conductive film being used as a first contact which contacts the drain region and which has a top lying at almost the same level as the surface of the first side insulating films.

14. The method according to claim 13, further comprising:
removing the cap insulating film, for exposing the gate electrodes;
forming silicide layers on the gate electrodes, drain regions and source regions and first contact;
forming a second insulating film on the entire surface of the resultant structure;
planarizing a surface of the second insulating film;
making a plurality of second holes in the second insulating film, for exposing the gate electrodes, drain regions, source regions and exposing the silicide layers formed on the gate electrodes; and
forming wire layers in the second holes, the wire layers being connected to the silicide layers.

15. The method according to claim 13, further comprising:
removing another first insulating film from the cell-array region at the same time the first hole is made, for making a third hole that exposes the source region; and
forming a conductive film in the third hole, the conductive film being used as a second contact which contacts the source region and which has a top lying at almost the same level as the surface of the first side insulating films.

16. The method according to claim 15, further comprising:
forming trench capacitors in the cell-array region before the gate structures are formed.

17. The method according to claim 15, further comprising:
forming a stack capacitor above the first contact.

18. The method according to claim 17, further comprising:
forming a bit line above the stack capacitor.

19. The method according to claim 17, further comprising:
forming a bit line below the stack capacitor before the stack capacitor is formed.

20. The method according to claim 17, wherein an active region having a projection is formed in the substrate, and two adjacent gate electrodes are formed on the sides of the projection.
